(19) United States
(12) Patent Application Publication
(10) Pub. No.: US 2010/0181549 A1
(43) Pub. Date: Jul. 22, 2010

(54) Phase-Changeable Random Access Memory Devices Including Barrier Layers and Metal Silicide Layers

(76) Inventors: Song-Yi Kim, Hwaseong-si (KR); Heung-Jin Joo, Suwon-si (KR); Dae-Hwan Kang, Seoul (KR); Ji-Hyun Jeong, Seoul (KR); Jun-Hyok Kong, Hwaseong-si (KR)

Correspondence Address: MYERS BIGEL SIBLEY & SAJOVEC, PO BOX 37428, RALEIGH, NC, 27627, US

(21) Appl. No.: 12/687,276

(22) Filed: Jan. 14, 2010

(30) Foreign Application Priority Data
Jan. 16, 2009 (KR) 10-2009-0003567

(51) Int. Cl. H01L 47/00

(52) U.S. Cl. 257/3; 257/E47.001

(57) ABSTRACT

A PRAM device may include an insulating interlayer, a diode, a metal silicide layer, a barrier spacer, an outer spacer, a lower electrode, a phase-changeable layer and an upper electrode. The insulating interlayer may be formed on a substrate. The insulating interlayer may have a contact hole. The diode may be formed in the contact hole. The metal silicide layer may be formed on the diode. The barrier spacer may be formed on an upper surface of the metal silicide layer and a side surface of the contact hole. The outer spacer may be formed on the barrier spacer. The lower electrode may be formed on the barrier spacer. The phase-changeable layer may be formed on the lower electrode. The upper electrode may be formed on the phase-changeable layer.

### CLAIM OF PRIORITY

This application claims priority to Korean Patent Application No. 10-2009-0003567, filed Jan. 16, 2009, the content of which is incorporated herein by reference as if set forth in its entirety.

### FIELD OF THE INVENTION

This invention generally to memory devices and, more particularly, to phase-changeable random access memory (PRAM) devices and methods of manufacturing the same.

### BACKGROUND

Generally, a semiconductor memory device may be classified as a volatile memory device, such as a dynamic random access memory (DRAM) device, a static random access memory (SRAM) device, that loses data over time and a non-volatile memory device that continuously stores data regardless of passage of time. The non-volatile memory device may include an electrically erasable programmable read only memory (EEPROM), a flash memory device, and the like, capable of electrically inputting/outputting data. This flash memory device may be a progressive type of the EEPROM capable of rapidly erasing data. The flash memory device electrically controls input/output of data using Fowler-Nordheim (F-N) tunneling or hot electrons.

The non-volatile memory device, such as the flash memory device, may be widely used in electronic devices, such as a digital camera, a cellular phone, an MP3 player, and the like. The flash memory device may require a long time for reading and writing data. Thus, a PRAM device, a magnetic random access memory (MRAM) device, a ferroelectric random access memory (FRAM) device, and the like, may have been developed in place of the flash memory device.

The PRAM device may store data using a resistance difference between an amorphous state and a crystal state converted by phase transition of chalcogenide compound. Particularly, the PRAM device may store the data as “0” and “1” using a reversible phase transition of a phase-changeable layer that may include the chalcogenide compound including a germanium(Ge)-antimony(Sb)-tellurium(Te) (GST) in accordance with an amplitude and a length of a pulse applied to the PRAM device.

Referring now to FIG. 1, a scanning electron microscope (SEM) picture illustrating a cell of a conventional PRAM device will be discussed. As illustrated in FIG. 1, a P-N diode may be formed on an N type semiconductor substrate. A bottom electrode contact (BEC) may be formed on the diode. A GST layer may be formed on the BEC. A top electrode contact (TEC) may be formed on the GST layer. A first metal line, such as a bit line, may be electrically connected with the TEC. A second metal line, such as a word line, may be connected with impurity regions in the semiconductor substrate through a contact. Further, a metal silicide layer may be formed between the P-N diode and the BEC. The metal silicide layer may reduce a resistance between the BEC and the diode. The metal silicide layer may include, for example, cobalt, tungsten, and the like.

Referring now to FIG. 2, a circuit diagram illustrating the PRAM device in FIG. 1 will be discussed. As illustrated in FIG. 2, the PRAM device may include a word line selector 30 and a bit line selector 40. Cells 10 may be electrically connected to the word line and the bit line.

Referring now to FIG. 3, a circuit diagram illustrating the cell of the PRAM device in FIG. 1 will be discussed. As illustrated in FIG. 3, the cell 10 of the PRAM device may include the P-N diode on the semiconductor substrate functioning as a diode D and a variable resistance R, and the GST layer between the BEC and the TEC.

Referring now to FIG. 4, in order to readily control the GST layer using a low current, it may be required to reduce a contact area between the BEC and the GST layer. Thus, the BEC may have preferably a small area. Although the BEC may have the small area, it may also be required to decrease a contact resistance between the BEC and the diode. Thus, the metal silicide layer may be formed between the diode and the BEC.

The PRAM device may read and write data using a very small resistance difference. Therefore, when a defect may be generated in the metal silicide layer, this may cause malfunctions of the PRAM device.

When an outer spacer may be formed by an etching process after forming the metal silicide layer, etching damages may be generated in the metal silicide layer.

In order to reduce the likelihood of or possibly prevent the metal silicide layer from being damaged, the outer spacer may be formed before forming the metal silicide layer. However, the metal silicide layer may not be formed on an upper edge of the diode. The metal silicide layer may have a bad profile, so that the resistance may be increased.

### SUMMARY

Some embodiments provide phase-changeable random access memory (PRAM) devices including a diode in a contact hole on a substrate; a metal silicide layer on the diode; a barrier spacer on an upper surface of the metal silicide layer and a side surface of the contact hole; and an outer spacer on the barrier spacer.

In further embodiments, the PRAM may further include an insulating interlayer on the substrate, wherein the insulating interlayer defines the contact hole therein; a lower electrode on the barrier spacer; a phase-changeable layer on the lower electrode; and an upper electrode on the phase-changeable layer.

In still further embodiments, the metal silicide layer may be cobalt.

In some embodiments, a dielectric layer pattern may be provided between the lower electrode and the phase-changeable layer.

In further embodiments, the lower electrode may have an annular shape.

In still further embodiments, an impurity region may be connected to the diode.

In some embodiments, a metal wiring may be connected to the upper electrode.

Further embodiments provide methods of manufacturing a phase-changeable random access memory (PRAM) device including forming a diode in a contact hole on a substrate; forming a metal silicide layer on the diode; forming a barrier spacer on an upper surface of the metal silicide layer and a side surface of the contact hole; and then forming an outer spacer on the barrier spacer.

In still further embodiments, forming the diode may be preceded by forming an insulating interlayer on the substrate and forming the contact hole through the insulating interlayer. The method may further include forming a lower electrode on the barrier spacer; forming a phase-changeable layer on the lower electrode; and forming an upper electrode on the phase-changeable layer.

In some embodiments, the dielectric layer may be planarized to form a dielectric layer pattern between the lower electrode and the phase-changeable layer.

Further embodiments of the present invention provide communications systems including a base station and a portable electronic device including a phase-changeable random access memory (PRAM) device. The PRAM includes a diode in a contact hole on a substrate; a metal silicide layer on the diode; a barrier spacer on an upper surface of the metal silicide layer and a side surface of the contact hole; and an outer spacer on the barrier spacer.

### BRIEF DESCRIPTION OF THE DRAWINGS

FIG. 1 is a scanning electron microscope (SEM) picture illustrating a conventional PRAM device.

FIG. 2 is a circuit diagram illustrating the PRAM device in FIG. 1.

FIG. 3 is a circuit diagram illustrating a cell of the PRAM in FIG. 1.

FIG. 4 is an SEM picture illustrating the cell of the PRAM in FIG. 3.

FIGS. 5 through 31 are cross sections illustrating processing steps in the fabrication of PRAM devices in accordance with some embodiments.

FIG. 32 is a block diagram illustrating a cellular phone network including the PRAM device of FIG. 31.

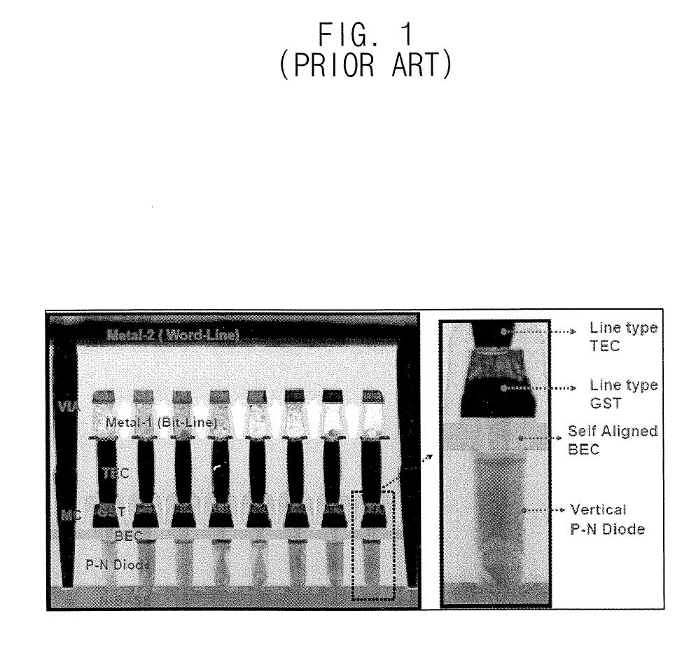

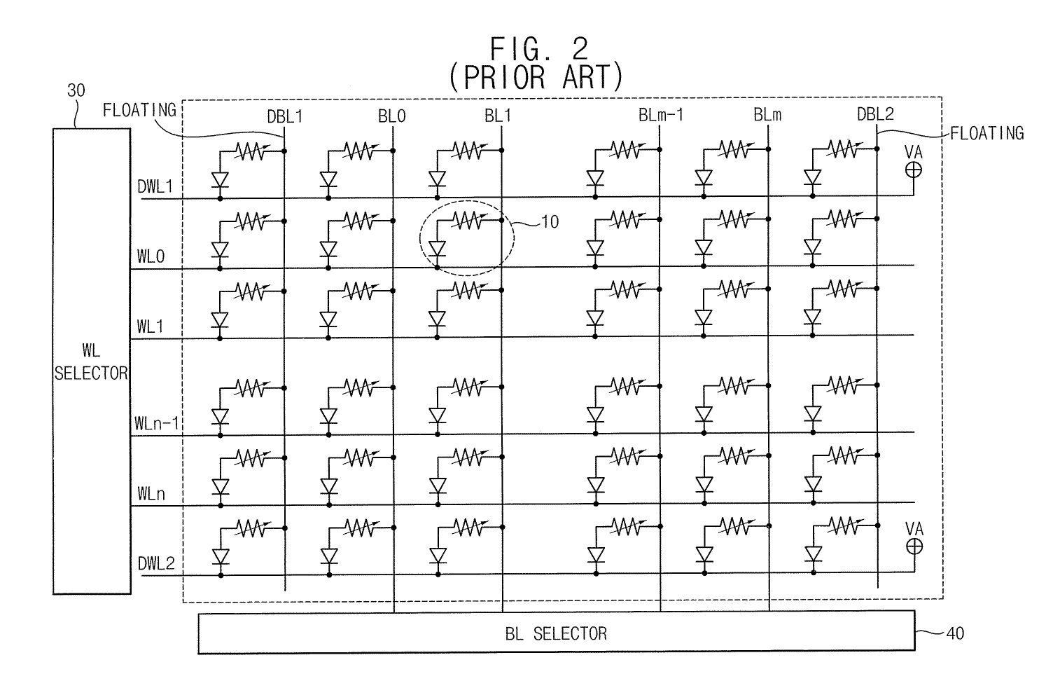

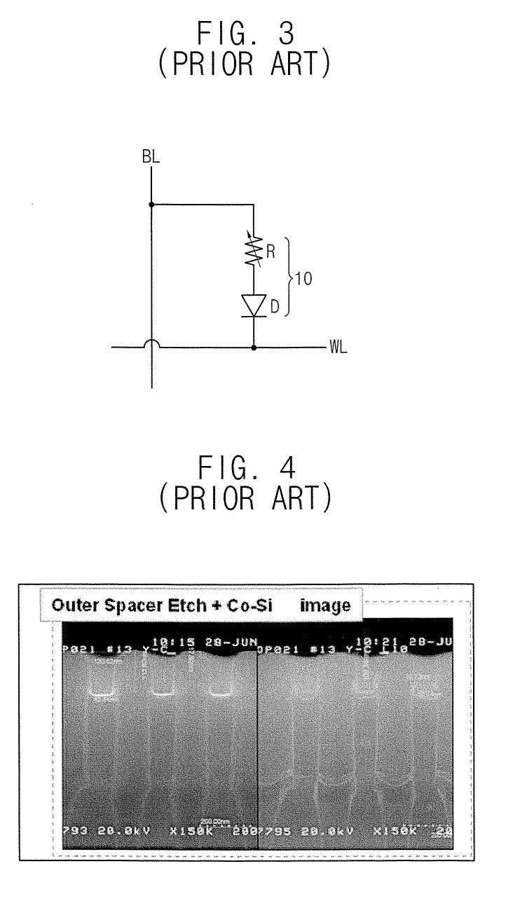

### DETAILED DESCRIPTION OF EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

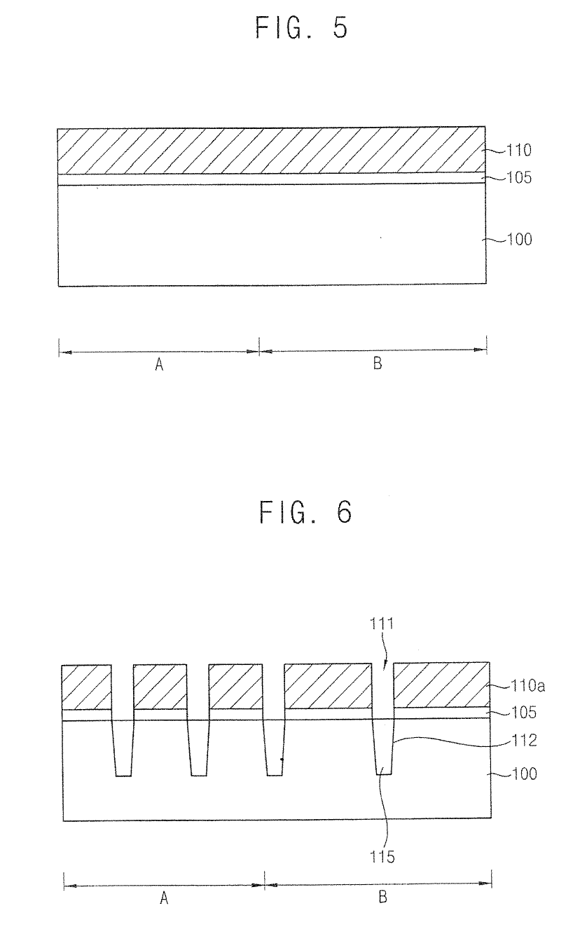

Hereinafter, example embodiments will be explained in detail with reference to the accompanying drawings. In particular, methods of manufacturing PRAM devices in accordance with some embodiments will be discussed with respect to FIGS. 5 through 31.

FIGS. 5 to 31 are cross-sections illustrating processing steps in the fabrication of PRAM devices in accordance with some embodiments. Referring first to FIG. 5, a pad oxide layer 105 may be formed on a semiconductor substrate 100. A nitride layer 110 may be formed on the pad oxide layer 105. In some example embodiments, the semiconductor substrate 100 may have a region A where memory cells may be formed, and a region B where peripheral circuits such as a high voltage transistor and a low voltage transistor may be formed.

In some embodiments, the pad oxide layer 105 may be formed by a thermal oxidation process. The pad oxide layer 105 may have a thickness of from about 100 Å to about 150 Å. The pad oxide layer 105 may function as a buffer layer for absorbing stresses in the nitride layer 110.

In some embodiments, the nitride layer 110 may be formed by a chemical vapor deposition (CVD) process. The nitride layer 110 may have a thickness of from about 1,000 Å to about 1,100 Å. In order to possibly improve properties of the nitride layer 110, the nitride layer 110 may be formed by two CVD processes. For example, a first nitride layer having a thickness of about 300 Å may be formed on the pad oxide layer 105. A second nitride layer having a thickness of from about 700 Å to about 800 Å may then be formed on the first nitride layer to complete the nitride layer 110.

Although not depicted in drawings, a hard mask layer may be formed on the nitride layer 110. In some embodiments, the hard mask layer may include an underlying layer, an organic layer and an anti-reflective layer sequentially stacked. The underlying layer may include an oxide layer or a nitride layer. The anti-reflective layer may include a nitride layer.

Referring now to FIG. 6, the nitride layer 110 may be etched to form a nitride layer pattern 110a. In some embodiments, a photoresist pattern (not shown) may be formed on the hard mask layer. The hard mask layer may be etched using the photoresist pattern as an etch mask to form a hard mask pattern (not shown). The nitride layer may be etched using the hard mask pattern as an etch mask to form the nitride layer pattern 110a having openings 111 configured to expose the pad oxide layer 105. Spacing between the openings in the region A may be narrower than spacing between the openings in the region B.

The pad oxide layer 105 and the semiconductor substrate 100 may be etched using the nitride layer pattern 110a as an etch mask to form trenches 112. In some example embodiments, in order to fill up the trenches 112 with isolation layers 115, the trenches 112 may have slanted side surfaces. The slanted side surfaces of the trenches 112 may distribute stresses, which may be caused by different properties between the isolation layers 115 and the semiconductor substrate 100, to reduce the likelihood or possibly prevent the stresses from being concentrated on the a channel region. The trenches 112 may have a depth of from about 2,000 Å to about 5,000 Å.

The trenches 112 may be filled with the isolation layers 115. In some embodiments, the semiconductor substrate 100 may be thermally oxidized to form an oxide layer. A middle temperature oxide (MTO) layer having a thickness of about 100 Å may be formed on the oxide layer. A high density plasma chemical vapor deposition (HDP-CVD) oxide layer may be formed on the MTO layer. The HDP-CVD oxide layer may be planarized by a chemical mechanical polishing (CMP) process to complete the isolation layer 115.

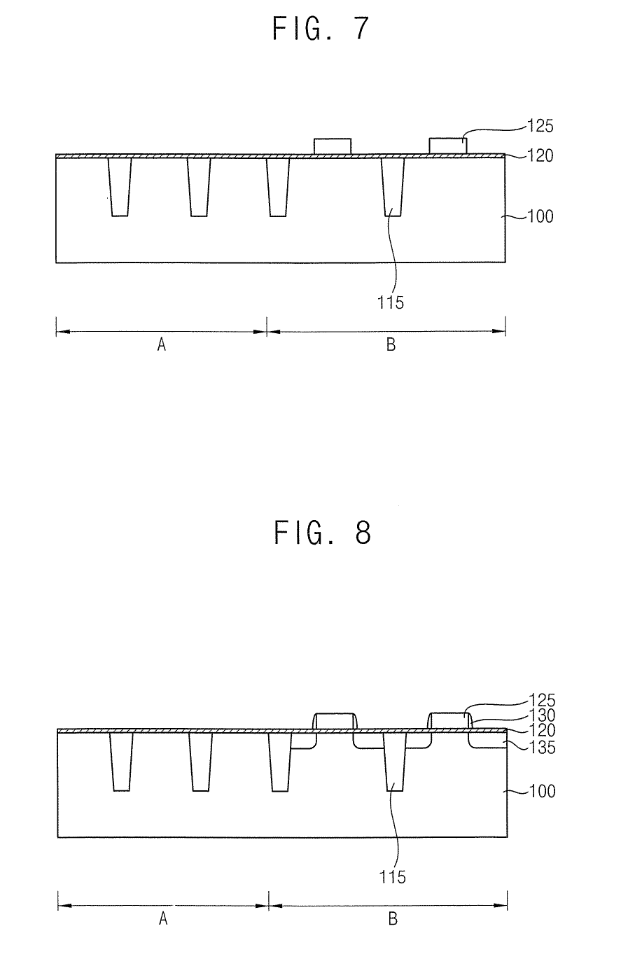

Referring now to FIG. 7, the nitride layer pattern 110a and the pad oxide layer 105 may be removed. A gate insulating layer 120 may be formed on the semiconductor substrate 100 and the isolation layers 115. A gate conductive layer (not shown) may be formed on the gate insulating layer 120. The gate conductive layer may be patterned to form gate electrodes 125 in the region B.

Referring now to FIG. 8, a spacer 130 may be formed on a sidewall of the gate electrode 125. In some embodiments, a nitride layer having a thickness of about 500 Å may be formed on the gate insulating layer 120 by a CVD process to cover the gate electrode 125. The nitride layer may be etched-back to form the spacer 130 on the sidewall of the gate electrode 125.

Impurities may be implanted into the semiconductor substrate 100 using the spacer 130 as an ion implantation mask to form heavily doped impurity regions 135 in the region B.

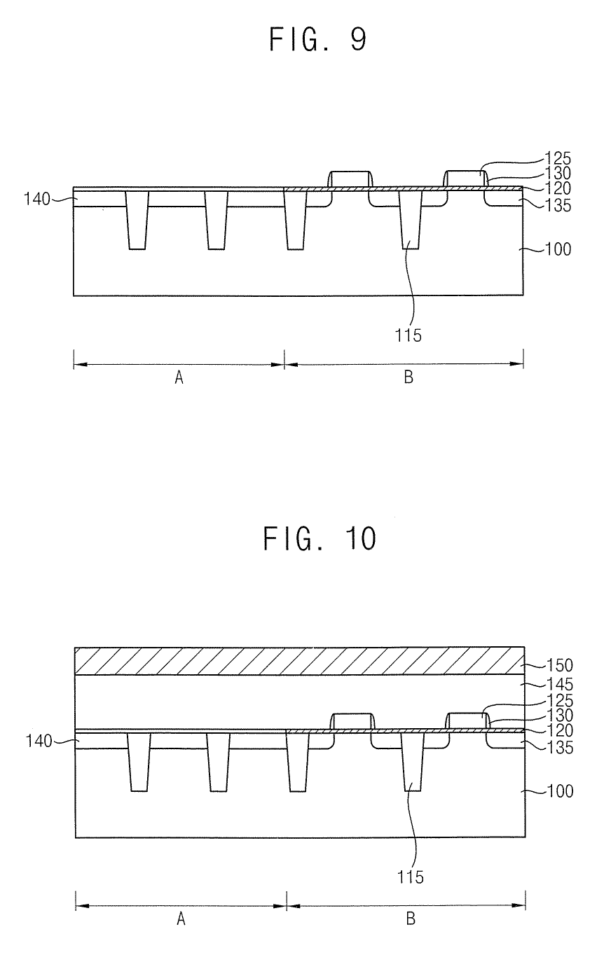

Referring now to FIG. 9, impurities may be implanted into the semiconductor substrate 100 in the region A to form a lower conductive layer 140. In some embodiments, the lower conductive layer 140 may be used as a word line. The impurities may include N type impurities.

Referring now to FIG. 10, a first insulating interlayer 145 may be formed on the gate insulating layer 120 to cover the gate electrode 125. A second insulating interlayer 150 may be formed on the first insulating interlayer 145.

In some embodiments, the first insulating interlayer 145 may be formed by forming an HDP-CVD oxide layer having a thickness of about 5,000 Å, and planarizing the HDP-CVD oxide layer. The second insulating interlayer 150 may include a nitride layer having a thickness of about 1,500 Å. Additionally, a third insulating interlayer (not shown) may be formed on the second insulating interlayer 150. In some embodiments, the third insulating interlayer may include an oxide layer.

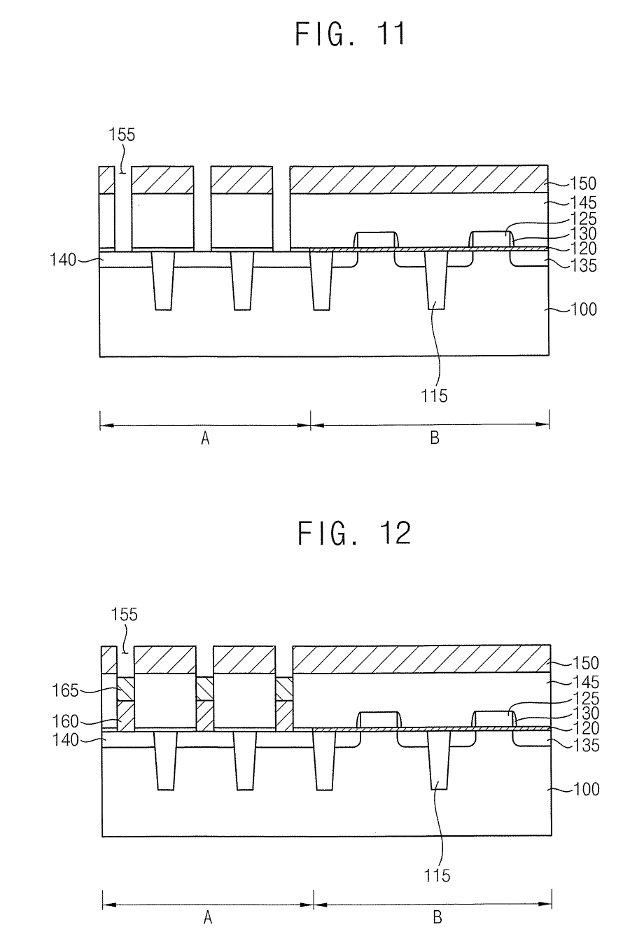

Referring now to FIG. 11, the second insulating interlayer 150 and the first insulating interlayer 145 may be etched to form openings 155 configured to expose the lower conductive layer 140. Additionally, spacers (not shown) may be formed on side surfaces of the openings 155.

Referring now to FIG. 12, an epitaxial growth process may be performed on the lower conductive layer 140 exposed through the openings 155 to form an epitaxial layer (not shown). In some embodiments, the epitaxial layer may have a thickness of from about 6,000 Å. The epitaxial layer may be planarized by a CMP process.

P type impurities may be implanted into a lower portion of the epitaxial layer to form a P type diode 160. N type impurities may be implanted into an upper portion of the epitaxial layer to form an N type diode 165, thereby completing a P-N diode 160 and 165. The epitaxial layer may be removed by an etch-back process to provide the P-N diode 160 and 165 with an upper surface lower than that of the first insulating interlayer 145.

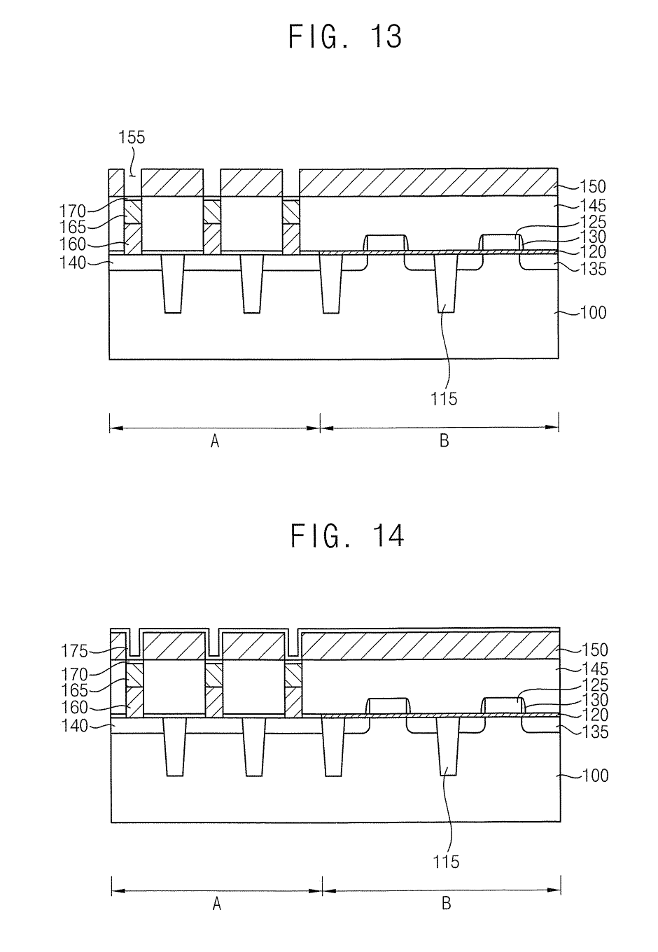

Referring now to FIG. 13, a metal silicide layer 170 may be formed on the P-N diode 160 and 165. In some embodiments, a metal layer (not shown) having a thickness of about 500 Å such as a cobalt layer or a titanium layer may be formed by a physical vapor deposition (PVD) process. The metal layer may be treated by a primary rapid thermal process (RTP) at a temperature of about 500° C. to form a cobalt silicide layer or a titanium silicide layer by bonding cobalt or titanium with silicon in the P-N diode 160 and 165.

A portion of the metal layer on the second insulating interlayer 150 non-reacted with the silicon may be removed to form the metal silicide layer 170 only on the P-N diode 160 and 165. The metal silicide layer 170 may be treated by a secondary RTP to stabilize the metal silicide layer 170, thereby reducing a resistance of the metal silicide layer 170.

In some embodiments, the metal silicide layer 170 may have an area substantially the same as that of the P-N diode 160 and 165. Thus, a gap may be formed between the metal silicide layer 170 and the P-N diode 160 and 165, so that the metal silicide layer 170 may have an improved profile.

Referring now to FIG. 14, a barrier layer 175 may be formed on the second insulating interlayer 150 and the metal silicide layer 170. The barrier layer 175 may reduce the likelihood or possibly prevent the metal silicide layer 170 from being damaged in following processes.

In some embodiments, the barrier layer 175 may include titanium/titanium nitride layer. The titanium/titanium nitride layer may be treated by a RTP for allowing the titanium/titanium nitride layer to be bonded with the cobalt silicide layer 170.

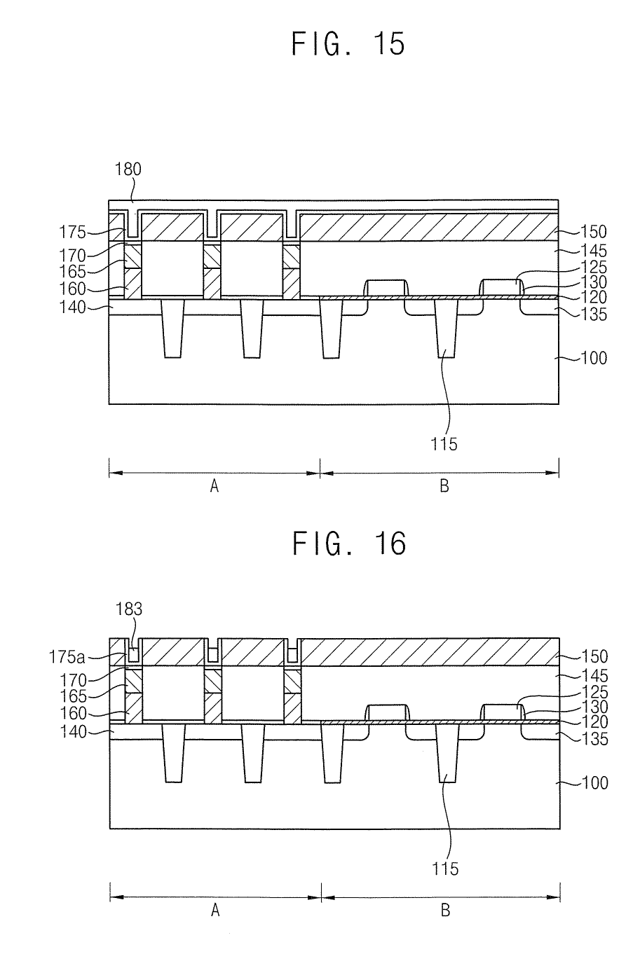

Referring now to FIG. 15, a sacrificial layer 180 may be formed on the barrier layer 175. In some embodiments, the sacrificial layer 180 may include a material having an etching selectivity different from etching selectivities of the second insulating interlayer 150 and the barrier layer 175. In embodiments where the second insulating interlayer 150 includes the nitride layer, the sacrificial layer 180 may include a silicon oxide layer or a polysilicon layer.

Referring now to FIG. 16, the sacrificial layer 180 and the barrier layer 175 may be planarized by a CMP process to form a preliminary sacrificial layer pattern (not shown) and a barrier layer pattern 175a in the opening 155. The preliminary sacrificial layer pattern may be etched-back using an etching gas to form a sacrificial layer pattern 183. The sacrificial layer pattern 183 may serve as a mask for etching the barrier layer 175.

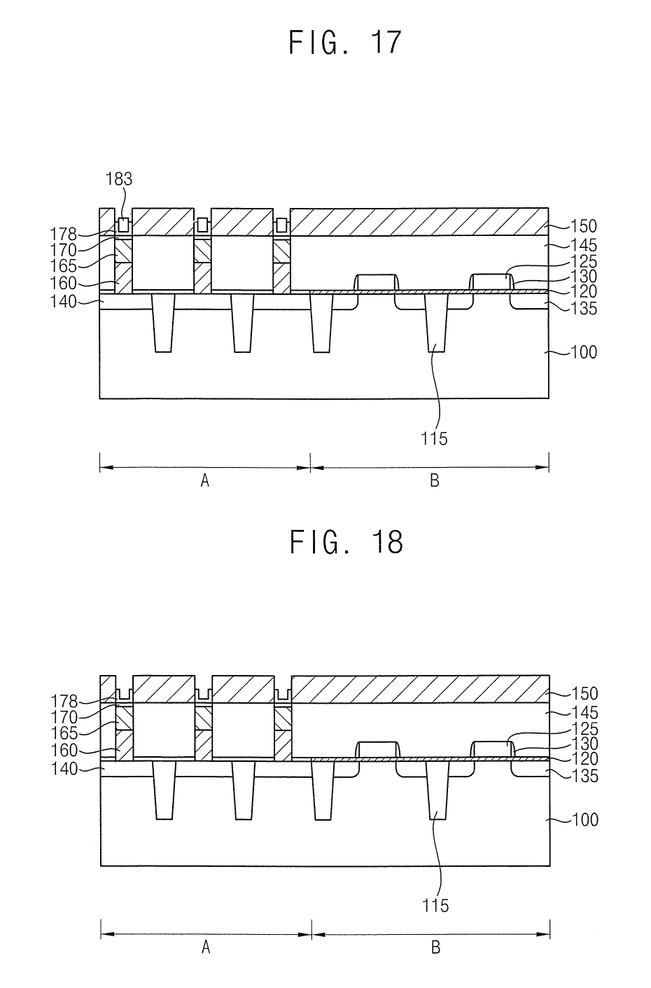

Referring now to FIG. 17, the barrier layer pattern 175a may be etched-back using the sacrificial layer pattern 183 as an etch mask to form a barrier spacer 178 on the side surfaces of the opening 155 in the second insulating interlayer 150.

In some embodiments, the barrier spacer 178 may have a U shape on an upper surface of the metal silicide layer 170 and the side surfaces of the opening 155 due to the shape of the sacrificial layer pattern 183. The barrier spacer 178 may function as to a protecting layer for reducing the likelihood or possibly preventing etching damages in forming an outer spacer.

Referring now to FIG. 18, the sacrificial layer pattern 183 may be removed by a wet etching process.

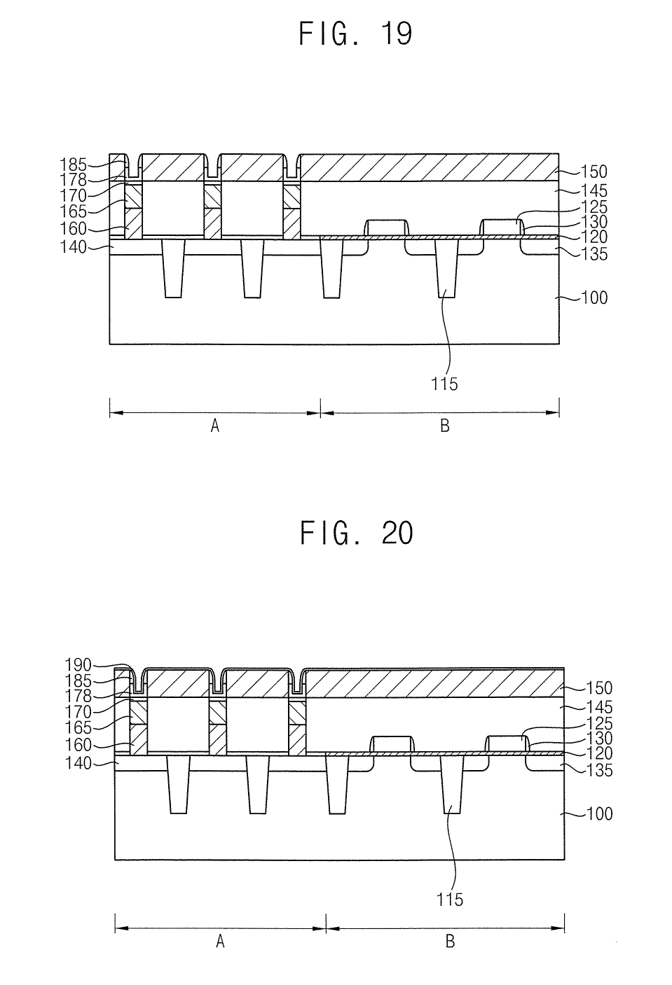

As illustrated in FIG. 19, an outer spacer 185 may be formed on the barrier spacer 178. In some embodiments, the outer spacer 185 may include an oxide layer and a nitride layer sequentially stacked. The oxide layer may have a thickness of about 100 Å. The nitride layer may have a thickness of about 500 Å.

In some embodiments, the outer spacer 185 may reduce an area of the opening 155 to reduce or possibly minimize a contact area between a lower electrode and a phase-changeable layer. The small contact area between the lower electrode and the phase-changeable layer may allow phase conversions of the phase-changeable layer using a small current.

Referring now to FIG. 20, a lower electrode 190 may be formed on the outer spacer 185, the barrier spacer 178 and the second insulating interlayer 150. In some embodiments, the lower electrode layer 190 may have a thickness of about 100 Å to about 300 Å. The lower electrode layer 190 may include a titanium nitride layer or a titanium/titanium nitride layer. Alternatively, the lower electrode layer 190 may include a tungsten layer, a tantalum layer, a molybdenum layer, a zirconium layer, and any combination thereof.

In some embodiments, the lower electrode layer 190 may have an annular shape. The annular shape of the lower electrode layer 190 may decrease the contact area between the lower electrode layer 190 and the phase-changeable layer.

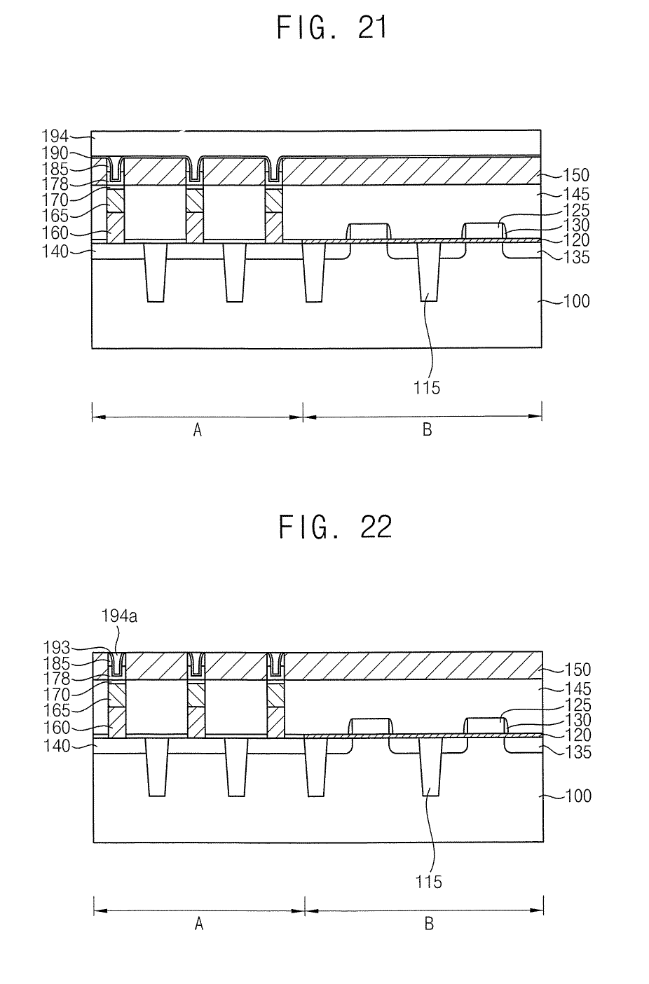

Referring now to FIG. 21, a dielectric layer 194 may be formed on the lower electrode layer 190. In some embodiments, the dielectric layer 194 may include an oxide layer, a nitride layer, and the like. Further, the dielectric layer 194 may be formed by a CVD process, an atomic layer deposition (ALD) process, and the like.

Referring now to FIG. 22, the dielectric layer 194 and the lower electrode layer 190 may be partially removed until an upper surface of the second insulating interlayer 150 may be exposed to form a dielectric layer pattern 194a and a lower electrode 193.

After performing the removal process, the annular lower electrode 193 may be positioned on the barrier spacer 178 and the outer spacer 185. The dielectric layer pattern 194a may be located on the annular lower electrode 193.

In some embodiments, the annular lower electrode 193 may have a small contact area with respect to a phase-changeable layer, so that the phase conversion of the phase-changeable layer may be readily controlled using a small current.

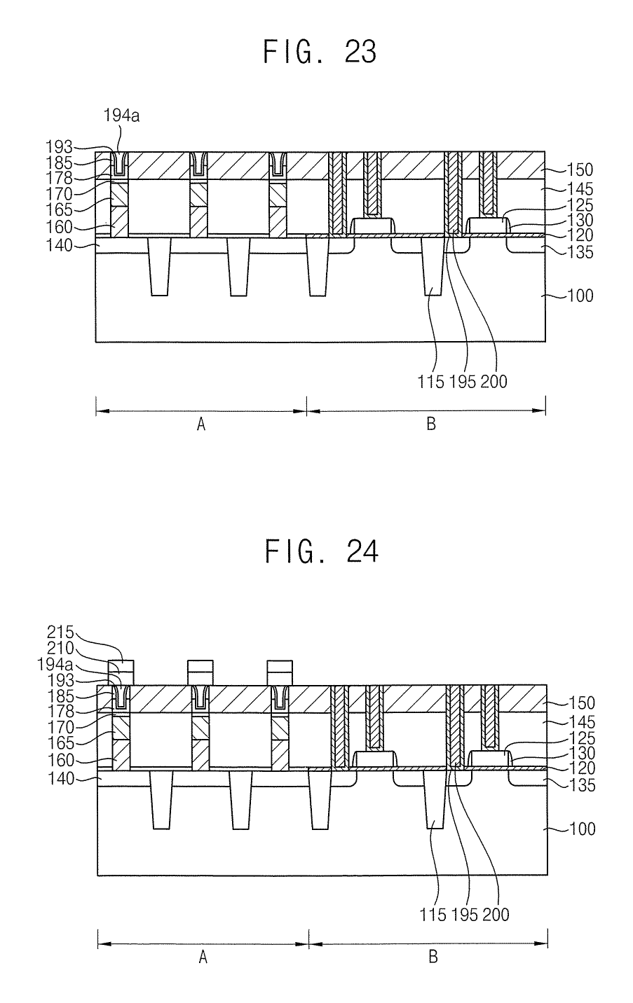

Referring now to FIG. 23, a hard mask (not shown) may be formed on the second insulating interlayer 150 in the region B. In some embodiments, the hard mask may include an underlying layer, an organic layer and an anti-reflecting layer sequentially stacked. The underlying layer may include an oxide layer, a nitride layer, and the like. The anti-reflective layer may include a nitride layer.

The second insulating interlayer 150 and the first insulating interlayer 145 may be etched using the hard mask as an etch mask to form contact holes configured to expose the gate electrode 125 and the gate insulating layer 120.

A barrier layer 195 may be formed on inner surfaces of the contact holes. In some embodiments, the barrier layer 195 may include a titanium layer, a titanium nitride layer, a titanium tungsten layer, a titanium/titanium nitride layer, and the like. In some embodiments, the contact holes may be filled with plugs 200. The plugs 200 may include tungsten.

Referring now to FIG. 23, the phase-changeable layer 210 may be formed on the dielectric layer pattern 194a and the lower electrode 193. In some embodiments, the phase-changeable layer 210 may be formed using a PVD apparatus.

In some example embodiments, the PVD apparatus may include a stage, a chalcogenide target and a power supply. The semiconductor substrate 100 may be placed on the stage.

The chalcogenide target may include chalcogenide compound including Ge₂Sb₂Te₅. Particularly, the chalcogenide target may include about 22% of germanium, about 22% of antimony and about 56% of tellurium.

Alternatively, the chalcogenide target may include a first target and a second target. The first target may include GeTe. The second target may include Sb₂Te₃.

Further, the chalcogenide target may additionally include impurities such as oxygen, silicon, carbon, nitrogen, etc. The impurities may function as to control a stabilization time of the chalcogenide compound in the sputtering process.

The power supply may apply a negative voltage to the chalcogenide target to form a voltage difference between the stage and the chalcogenide target.

A process temperature may be provided with a process chamber of the PVD apparatus. In some embodiments, the process temperature may volatilize the tellurium. Particularly, the process temperature may be lower than a volatilization temperature of antimony and higher than a volatilization temperature of tellurium.

Generally, the germanium may have a melting temperature of about 938° C. The antimony may have a melting temperature of about 631° C. The tellurium may have a melting point of about 450° C.

Although the chalcogenide compound may have a metal property, the chalcogenide compound may have a vitrification temperature because the chalcogenide compound may not be a metal. Thus, the germanium, the antimony and the tellurium in the chalcogenide compound may be volatilized no less than at vitrification temperatures of the germanium, the antimony and the tellurium. The tellurium may have the lowest vitrification temperature of from about 250° C. to about 300° C.

Therefore, the process chamber may be provided with a temperature of about 250° C. to about 300° C. higher than the vitrification temperature of the tellurium and lower than the vitrification temperature of the antimony. The process temperature in the process chamber may be maintained by a heater in the stage.

Plasma including argon ions may be formed in the process chamber. In some embodiments, a negative voltage may be applied to the chalcogenide target to form a voltage difference between the stage and the chalcogenide target. The voltage may be from about 300W to about 700W, preferably about 500W.

An argon gas may be introduced into the process chamber. The argon gas may be excited to generate the plasma. Here, applying the voltage and the introducing the argon gas may be performed simultaneously with each other.

In some embodiments, the argon gas may be introduced into the process chamber at a flux of about 30 standard cubic centimeters (sccm) to about 80 sccm. In some embodiments, gas may be introduced into the process chamber at a flux of about 40 sccm to about 60 sccm.

Additionally, a nitrogen gas may be introduced into the process chamber. In some embodiments, the nitrogen gas may be introduced into the process chamber at a flux of from about 10 sccm to about 100 sccm. In some embodiments, the nitrogen gas may be introduced into the process chamber at a flux from about 25 sccm to about 80 sccm.

When the argon gas and the nitrogen gas may be introduced into the process chamber together with each other, a flux ratio between the argon gas and the nitrogen gas may be about 1:0.3 to about 1:2.0, preferably about 1:0.35 to about 1:1.5.

Here, the nitrogen gas may function as to increase a formation time of the chalcogenide compound by decreasing deposition speeds of particles, which may be detached from the chalcogenide target, on the semiconductor substrate 100. That is, the nitrogen gas may control a content of the tellurium by no more than about 50% in the chalcogenide compound by facilitating the volatilization of the tellurium.

The phase-changeable layer 210 may be formed in the process chamber where the plasma including the argon ions may be generated. In some embodiments, the phase-changeable layer 210 may include about 5% to about 50% of the tellurium.

In some embodiments, the argon ions in the plasma may collide against the chalcogenide target to detach the particles from the chalcogenide target. The detached particles may be physisorbed on the semiconductor substrate 100 to form a preliminary chalcogenide compound.

Here, because the preliminary chalcogenide compound may be unstable, the tellurium in the preliminary chalcogenide compound may be partially volatilized when the preliminary chalcogenide compound may be exposed to the temperature of from about 250° C. to about 300° C.

After the tellurium may be partially volatilized, the phase-changeable layer 210 including the chalcogenide compound may be formed on the semiconductor substrate 100. In some embodiments, the phase-changeable layer 210 may include from about 5% to about 50%, and in some embodiments from about 30% to about 50% of the tellurium.

For example, the phase-changeable layer 210 may include about 100% of the chalcogenide compound including about 25% to about 35%, about 25% to about 35% of the antimony, and about 30% to about 50% of the tellurium. Preferably, the phase-changeable layer 210 may include about 86% to about 98% of the chalcogenide compound including about 25% to about 35%, preferably about 25% to about 35% of the antimony and about 30% to about 50% of the tellurium, and about 2% to about 14% of the impurities. More preferably, the phase-changeable layer 210 may include about 90% to about 98% of the chalcogenide compound including about 25% to about 35%, about 25% to about 35% of the antimony and about 30% to about 50% of the tellurium, and about 2% to about 10% of the nitrogen.

An upper electrode 215 may then be formed on the phase-changeable layer 210. In some example embodiments, the upper electrode 215 may include a titanium/titanium nitride layer. Further, the upper electrode 215 may have a thickness of about 800 Å.

In some example embodiments, the phase-changeable layer 210 may be interposed between the lower electrode 193 and the upper electrode 215. Particularly, the phase-changeable layer 210 may have a lower surface making contact with the annular lower electrode 193, so that the contact area between the phase-changeable layer 210 and the annular lower electrode 193 may be very small. In contrast, an entire upper surface of the phase-changeable layer 210 may make contact with an entire lower surface of the upper electrode 215. As a result, the PRAM device may be operated using a small current, so that the PRAM device may have improved operational characteristics.

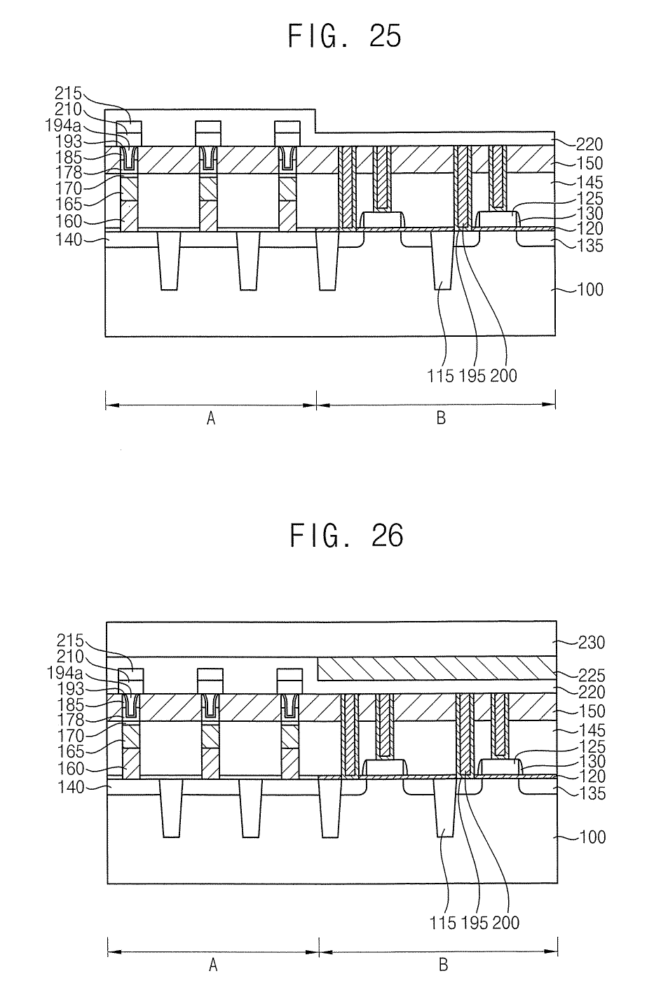

Referring now to FIG. 25, a capping layer 220 may be formed on the second insulating interlayer 150 to cover the phase-changeable layer 210 and the upper electrode 215. Thus, the capping layer 220 may have a stepped portion due to the phase-changeable layer 210 and the upper electrode 215.

In some embodiments, the capping layer 220 may include a nitride layer and an aluminum oxide layer sequentially stacked. The nitride layer may have a thickness of about 1,000 Å. The aluminum oxide layer may have a thickness of about 50 Å.

In some embodiments, the capping layer 220 may reduce the likelihood of or possibly prevent impurities in an insulating interlayer, which may be formed on the phase-changeable layer 210, from infiltrating into the phase-changeable layer 210. When the impurities may infiltrate into the phase-changeable layer 210, the phase-changeable layer 210 may not be used in the PRAM device.

Referring now to FIG. 26, a third insulating interlayer 225 may be formed on the capping layer 220. The third insulating interlayer 225 may be planarized until the third insulating interlayer 225 may have an upper surface substantially coplanar with that of the capping layer 220. In some embodiments, the third insulating interlayer 225 may include P-TEOS having a thickness of about 3,000 Å.

A fourth insulating interlayer 230 may be formed on the capping layer 220 and the third insulating interlayer 225. In some embodiments, the fourth insulating interlayer 230 may include a USG layer and a P-TEOS layer sequentially stacked. The USG layer may have a thickness of about 3,000 Å. The P-TEOS layer may have a thickness of about 6,000 Å.

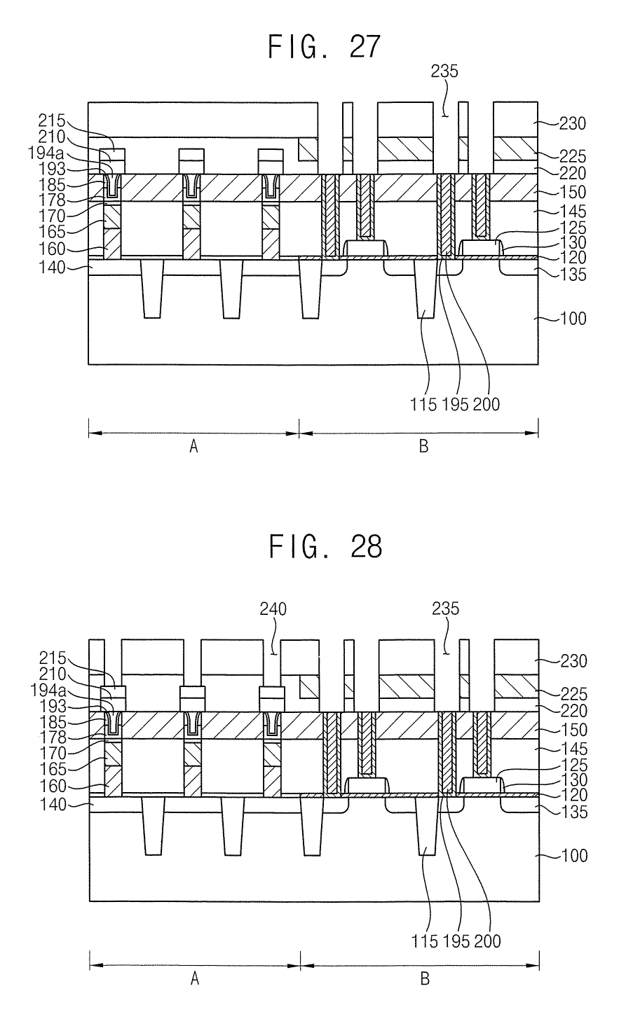

Referring now to FIG. 27, the fourth insulating interlayer 230, the third insulating interlayer 225 and the second insulating interlayer 220 in the region B may be etched to form openings 235 configured to expose the plugs 200.

Referring now to FIG. 28, the fourth insulating interlayer 230 and the second insulating interlayer 220 in the region A may be etched to form contact holes 240 configured to expose the upper electrodes 215.

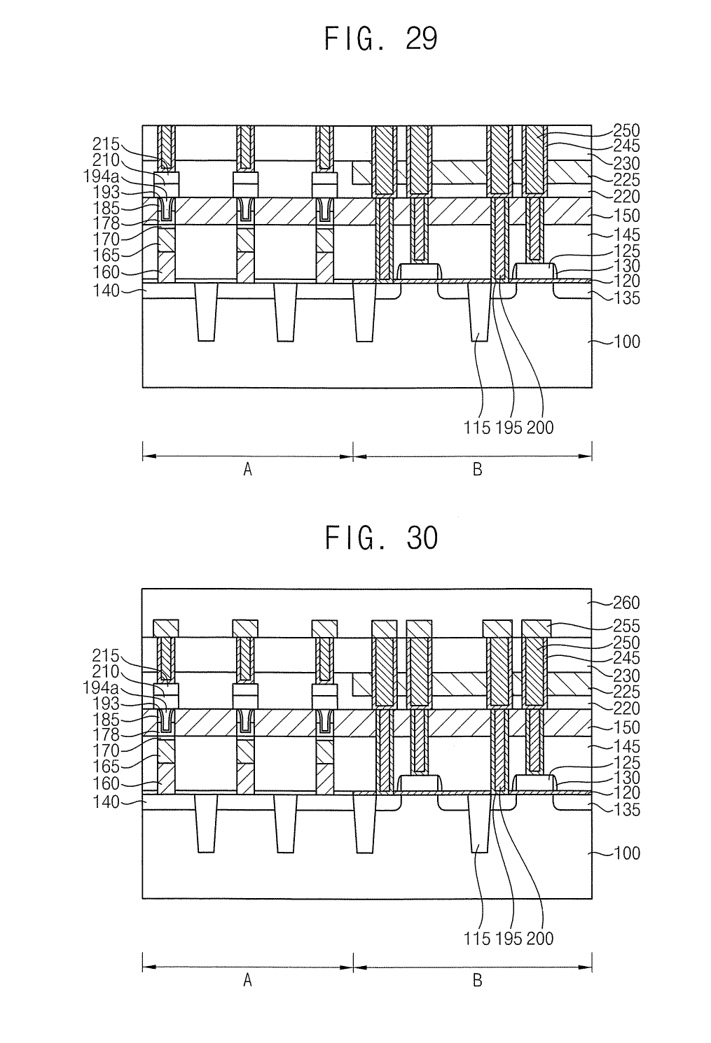

Referring now to FIG. 29, a barrier layer 245 may be formed on inner surfaces of the openings 235 and the contact holes 240. In some embodiments, the barrier layer 245 may be formed by a sputtering process. The barrier layer 245 may have a thickness of about 100 Å. The barrier layer 245 may include a titanium layer, a titanium nitride layer, a titanium tungsten layer, a titanium/titanium nitride layer, and the like.

A tungsten layer (not shown) may be formed in the fourth insulating interlayer 230 to fill up the openings 235 and the contact holes 240. The tungsten layer may be planarized to form tungsten plugs 250 in the openings 235 and the contact holes 240.

Referring now to FIG. 30, lower metal wirings 255 may be formed on the tungsten plugs 250. In some embodiments, the lower metal wirings 255 may include aluminum.

A fifth insulating interlayer 260 may be formed on the fourth insulating interlayer 230 to cover the lower metal wirings 255. In some embodiments, the fifth insulating interlayer 260 may include an HDP-CVD oxide layer and a P-TEOS layer sequentially stacked. The HPD-CVD layer may have a thickness of about 4,000 Å. The P-TEOS layer may have a thickness of about 6,000 Å.

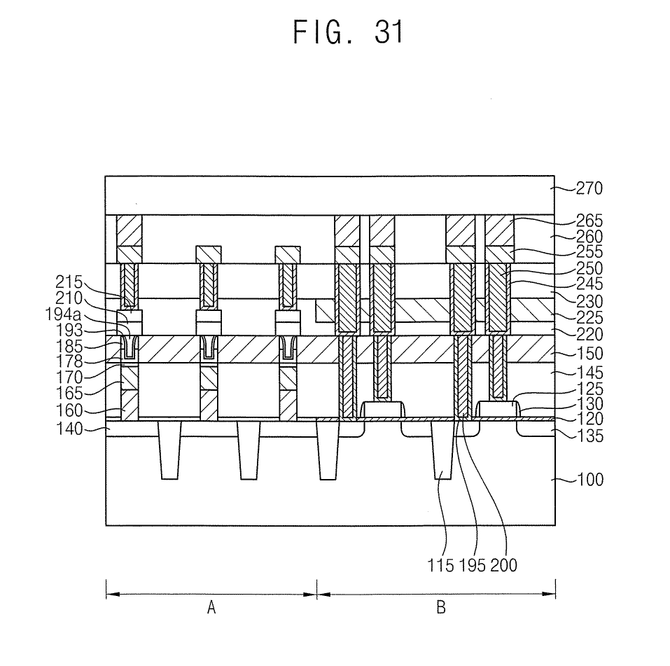

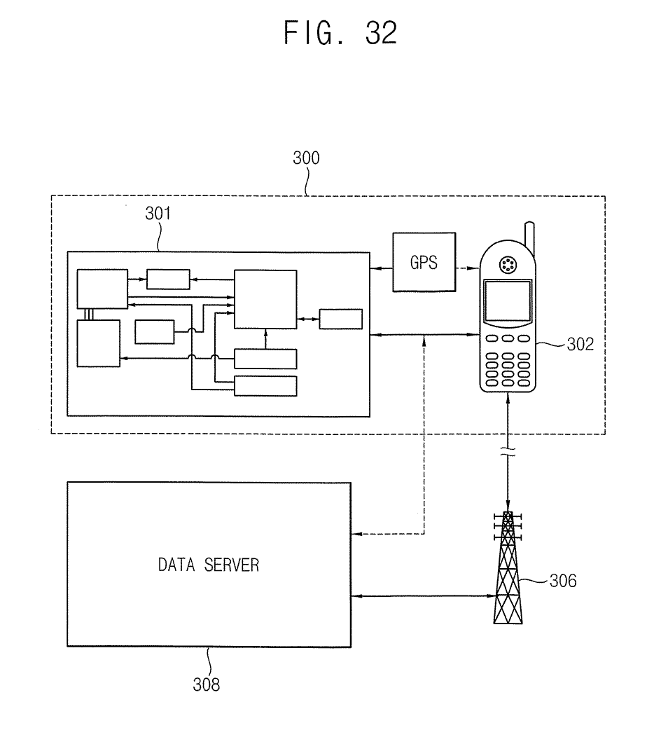

Referring now to FIG. 31, the fifth insulating interlayer 260 may be etched to form openings configured to expose the lower metal wirings 255. The openings may be filled with upper wirings 265. A protecting layer 270 may be formed on the upper wirings 265 and the fifth insulating interlayer 260.

According to some embodiments, the barrier spacer may protect the metal silicide layer on the PN diode. The metal silicide layer may not be damaged in the etching process for forming the phase-changeable layer. As a result, the PRAM device may have improved electrical characteristics.

Referring now to FIG. 32, a block diagram illustrating a cellular phone network including the PRAM device in FIG. 31 will be discussed. As illustrated in FIG. 32, a broadband mobile communication system 300 may include a sensor module 301 and a portable electronic device, for example, a cellular phone 302. The broadband mobile communication system 300 may communicate with a data server 309 and a base station 306.

The cellular phone 302 may include the PRAM device of FIG. 31 in accordance with some embodiments discussed herein. Thus, any further illustrations with respect to the PRAM device are omitted herein for brevity.

According to some embodiments, the barrier spacer may protect the metal silicide layer on the PN diode. The metal silicide layer may not be damaged in the etching process for forming the phase-changeable layer. As a result, the PRAM device may have improved electrical characteristics.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A phase-changeable random access memory (PRAM) device comprising:
an insulating interlayer on the substrate, wherein the insulating interlayer defines the contact hole therein;
a diode in the contact hole;
a metal silicide layer on the diode;
a barrier spacer on an upper surface of the metal silicide layer and a side surface of the contact hole;
an outer spacer on the barrier spacer;
a lower electrode on the barrier spacer;
a phase-changeable layer on the lower electrode; and
an upper electrode on the phase-changeable layer.

2. The PRAM device of claim 1, wherein the metal silicide layer comprises cobalt.

3. The PRAM device of claim 1, further comprising a dielectric layer pattern between the lower electrode and the phase-changeable layer.

4. The PRAM device of claim 1, wherein the lower electrode has an annular shape.

5. The PRAM device of claim 1, further comprising an impurity region connected to the diode.

6. The PRAM device of claim 1, further comprising a metal wiring connected to the upper electrode.

7.-10. (canceled)

11. A communications system, the system including:
a base station; and
a portable electronic device, the portable electronic device including a phase-changeable random access memory (PRAM) device, the PRAM comprising:
a diode in a contact hole on a substrate;
a metal silicide layer on the diode;
a barrier spacer on an upper surface of the metal silicide layer and a side surface of the contact hole; and
an outer spacer on the barrier spacer.

12. The system of claim 11, wherein the PRAM further comprises:
an insulating interlayer on the substrate, wherein the insulating interlayer defines the contact hole therein;
a lower electrode on the barrier spacer;
a phase-changeable layer on the lower electrode; and
an upper electrode on the phase-changeable layer.

13. The system of claim 12, wherein the metal silicide layer comprises cobalt.

14. The system of claim 12, wherein the PRAM further comprises a dielectric layer pattern between the lower electrode and the phase-changeable layer.

15. The system of claim 12, wherein the lower electrode has an annular shape.

16. The system of claim 12, wherein the PRAM further comprises an impurity region connected to the diode.

17. The system of claim 12, wherein the PRAM further comprises a metal wiring connected to the upper electrode.
